(19) United States
(12) Patent Application Publication
(10) Pub. No.: US 2025/0216734 A1
(43) Pub. Date: Jul. 3, 2025

(54) ARRAY SUBSTRATE AND DISPLAY DEVICE

(71) Applicant: Sharp Display Technology Corporation, Kameyama City (JP)

(72) Inventors: Yohei Takeuchi, Kameyama City (JP); Tatsuya Kawasaki, Kameyama City (JP); Kengo Hara, Kameyama City (JP); Masafumi Sugino, Kameyama City (JP); Hajime Imai, Kameyama City (JP)

(21) Appl. No.: 18/953,364

(22) Filed: Nov. 20, 2024

(30) Foreign Application Priority Data
Dec. 28, 2023 (JP) 2023-222459

(51) Int. Cl. G02F 1/1362; G02F 1/1368; H01L 27/12

(52) U.S. Cl. CPC G02F 1/13629; G02F 1/1368; H10D 86/441; H10D 86/60

(57) ABSTRACT

An array substrate includes a gate line, a source line crossing the gate line, a switching component disposed on a crossing portion of the gate line and the source line, a semiconductor film included in the switching component, a first insulating film disposed between a layer including the gate line and a layer including the semiconductor film, and a second insulating film disposed between a layer including the semiconductor film and a layer including the source line. The source line overlaps the gate line via the first insulating film and the second insulating film.

### CROSS REFERENCE TO RELATED APPLICATION

This application claims priority from Japanese Patent Application No. 2023-222459 filed on Dec. 28, 2023. The entire contents of the priority application are incorporated herein by reference.

### TECHNICAL FIELD

The present technology described herein relates to an array substrate and a display device.

### BACKGROUND

An array substrate of a liquid crystal display device has been known. In one example of such array substrates, as the thickness of lines increases, a cross-sectional area of the lines increases and a resistance value is decreased. With the resistance value being decreased, the time constant is decreased and signal delay can be decreased.

The time constant τ of a signal transmission circuit (RC circuit) is represented by τ=RC and is determined by an electrostatic capacity C (parasitic capacity) in addition to a resistance value R. According to the driving voltage of the transistor to which the signal is input and the resistance value of a surrounding circuit, decrease of the parasitic capacitance of the transmission circuit may effectively suppress the signal delay rather than the decrease of the resistance value of the transmission circuit.

### SUMMARY

The technology described herein was made in view of the above circumstances. An object is to reduce a parasitic capacitance of a line and suppress signal delay.
(1) An array substrate according to the technology described herein includes a gate line, a source line crossing the gate line, a switching component disposed on a crossing portion of the gate line and the source line, a semiconductor film included in the switching component, a first insulating film disposed between a layer including the gate line and a layer including the semiconductor film, and a second insulating film disposed between a layer including the semiconductor film and a layer including the source line. The source line overlaps the gate line via the first insulating film and the second insulating film.
(2) In the array substrate, in addition to (1), the switching component may include a source electrode that is connected to the semiconductor film, the source line may be connected to the source electrode and connected to the semiconductor film via the source electrode, and the source electrode may be disposed between the first insulating film and the second insulating film.
(3) In the array substrate, in addition to (1) or (2), the source electrode may not overlap the gate line.
(4) The array substrate may further include, in addition to any one of (1) to (3), a relay electrode. The switching component may include a drain electrode that is connected to the semiconductor film, the relay electrode may be connected to the drain electrode and connected to the semiconductor film via the drain electrode, and the drain electrode may be disposed between the first insulating film and the second insulating film.
(5) A display device according to the technology described herein includes the array substrate according to any one of (1) to (4) and an opposed substrate opposed to the array substrate.

According to the technology described herein, a parasitic capacitance of a line is reduced and signal delay is suppressed.

### BRIEF DESCRIPTION OF THE DRAWINGS

FIG. 1 is a plan view of a liquid crystal panel.

FIG. 2 is a cross-sectional view of the liquid crystal panel.

FIG. 3 is an enlarged plan view of a portion of an array substrate.

FIG. 4 is an enlarged plan view of a portion of the array substrate near a TFT in FIG. 3.

FIG. 5 is a cross-sectional view taken along A-A line in FIG. 4.

FIG. 6 is a view illustrating signal waveforms of transmitted shade signals.

FIG. 7 is a cross-sectional view of an array substrate of a conventional configuration corresponding to the cross-sectional view taken along line A-A in FIG. 4.

### DETAILED DESCRIPTION

### Embodiment

One embodiment will be described with reference to

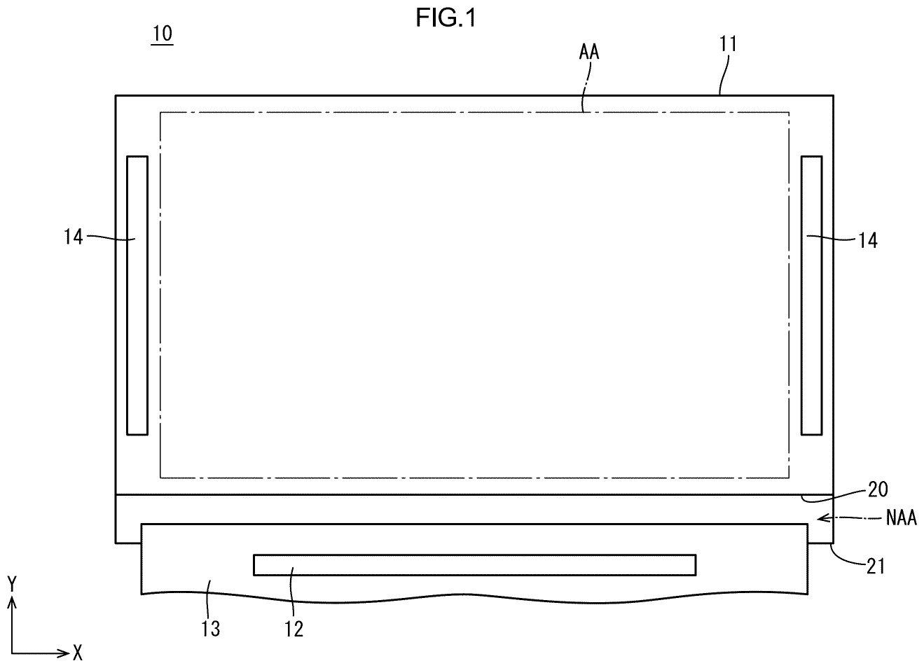

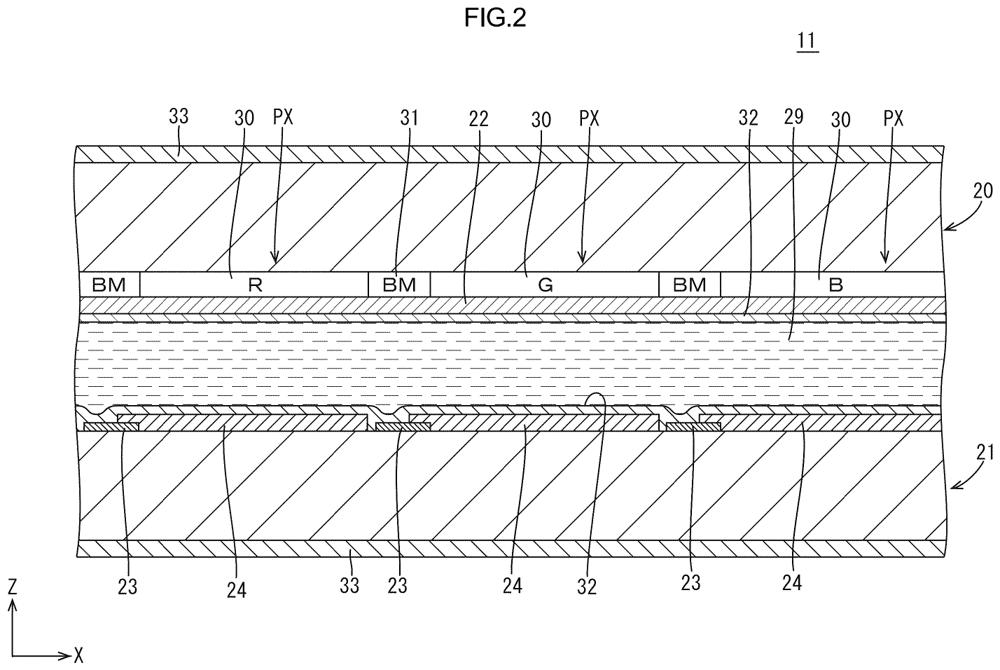

FIGS. 1 to 6. In this embodiment section, a liquid crystal panel 11 (one example of a display panel) of a liquid crystal display device 10 (one example of a display device) will be descried. X-axes, Y-axes, and Z-axes may be present in the drawings. The axes in each drawing correspond to the respective axes in other drawings. An upper-bottom direction is defined with reference to FIG. 2 and an upper side and a lower side in FIG. 2 correspond to a front side and a back side of the liquid crystal display device 10, respectively.

### 1. Description of Liquid Crystal Panel

FIG. 1 is a plan view of the liquid crystal panel 11. As illustrated in FIG. 1, the liquid crystal panel 11 has a laterally long rectangular plan view shape as a whole. A long-side direction and a short-side direction of the liquid crystal panel 11 matches the X-axis direction and the Y-axis direction, respectively, and a thickness direction of the liquid crystal panel 11 matches the Z-axis direction.

The liquid crystal panel 11 displays an image with using light from a backlight unit (a lighting device). A middle section of a screen of the liquid crystal panel 11 is configured as a display area AA (a pixel area) in which images are displayed. An outer section in a frame shape surrounding the display area AA in the screen of the liquid crystal panel 11 is configured as a non-display area NAA (a frame area) in which the images are not displayed. In FIG. 1, an area surrounded by a dashed dotted line is the display area AA.

As illustrated in FIG. 1, the liquid crystal panel 11 includes a pair of glass substrates 20, 21 that are substantially transparent and have highly transmissive properties. One of the substrates 20, 21 on the front side is an opposed substrate 20 (a CF substrate) and another one on the back side is an array substrate 21 (an active matrix substrate, a component substrate). The opposed substrate 20 and the array substrate 21 include various kinds of films that are formed in layers on an inner surface side of the glass substrates.

The array substrate 21 has a short-side dimension that is greater than a short-side dimension of the opposed substrate 20. A long side edge section of the array substrate 21 does not overlap the opposed substrate 20. On the non-overlapping section, a driver 12 (a signal supply section, a mount component) and a flexible substrate 13 (a mount component) are mounted on the non-overlapping section. The driver 12 is an LSI chip including a driver circuit therein. The driver 12 is mounted on a mounting area of the array substrate 21 through the chip-on-glass (COG) technology. The driver 12 processes various kinds of signals transmitted via the flexible substrate 13.

The driver 12 is mounted on the flexible substrate 13. The driver 12 is an LSI chip including a driver circuit therein. The driver 12 is mounted on the flexible substrate 13 and processes various kinds of signals supplied from an external control board.

Gate circuits 14 are disposed in the non-display area NAA of the array substrate 21. Two gate circuits 14 are disposed to sandwich the display area AA with respect to the X-axis direction. The two gate circuits 14 are disposed on two sides (a left side and a right side in FIG. 1) of the display area AA with respect to the X-axis direction. The gate circuits 14 are for supplying scan signals to gate lines 26, which will be described later. The gate circuits 14 are monolithically fabricated on the array substrate 21 with a metal film including portions that are configured as the gate lines 26 and source lines 27. The gate circuit 14 includes a shift resister circuit that is configured to output the scan signal at a predetermined timing.

The flexible substrate 13 includes a synthetic resin substrate (e.g., polyimide-based resin substrate) having insulating properties and flexibility and multiple traces formed on the substrate. A first end of the flexible substrate 13 is connected to the array substrate 21 and a second end of the flexible substrate 13 is connected to a control board (a signal supply). Various kinds of signals supplied from the control board are transmitted to the liquid crystal panel 11 via the flexible substrate 13.

FIG. 2 is a cross-sectional view of the display area AA of the liquid crystal panel 11. As illustrated in FIG. 2, the liquid crystal panel 11 includes a liquid crystal layer 29 between the substrates 20 and 21. The liquid crystal layer 29 includes liquid crystal molecules having optical characteristics that vary according to application of a voltage.

Color filters 30 that exhibit three different colors of red (R), green (G), and blue (B) are disposed in the display area AA on the inner surface side of the opposed substrate 20. The color filters 30 are arranged to overlap pixel electrodes 24 of the array substrate 21, respectively, in a plan view. A light blocking portion 31 is disposed between the adjacent color filters 30. The light blocking portion 31 functions as a dividing border between the color filters 30. In the liquid crystal panel 11, the color filters R, G, B that are arranged in the X-axis direction and the three pixel electrodes 24 that are opposite the color filters R, G, B, respectively, are configured as pixels PX of three colors.

The opposed substrate 20 includes an opposed electrode 22 that is disposed in a solid manner on a substantially entire area of the display area AA. The opposed electrode 22 is made of transparent electrode material similar to the material of the pixel electrodes 24 and is disposed opposite all the pixel electrodes 24 arranged in the display area AA with having the liquid crystal layer 29 therebetween.

Alignment films 32 are disposed on innermost surfaces of the substrates 20 and 21. Polarizing films 33 are disposed on outermost surfaces of the substrates 20, 21.

### 2. Lines and TFT

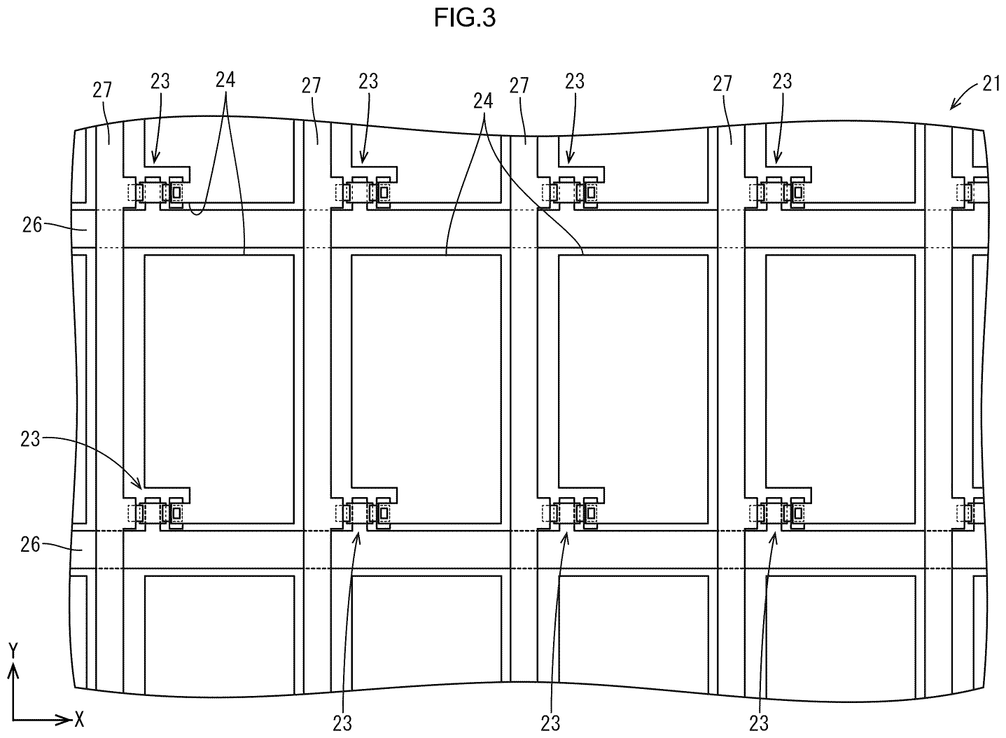

FIG. 3 is an enlarged view illustrating the display area AA of the array substrate 21. As illustrated in FIG. 3, on an inner surface side of the array substrate 21 in the display area AA, gate lines 26 (lines, scanning lines) and source lines 27 (lines, image lines) are routed in a grid form.

The gate lines 26 extend laterally in the display area AA along the X-axis direction. The source lines 27 extend vertically in the display area AA along the Y-axis direction. The gate lines 26 are arranged at intervals with respect to the Y-axis direction. The source lines 27 are arranged at intervals with respect to the X-axis direction. The gate lines 26 and the source lines 27 are portions of two different metal films that are included in different layers disposed via at least a gate insulating film F2.

The gate lines 26 and the source lines 27 cross in a view of the Z-axis direction and a TFT 23 (one example of a switching component) is disposed near each crossing portion. Each rectangular area surrounded by the gate lines 26 and the source lines 27 corresponds to the pixel PX. On an inner side of the pixel PX, a pixel electrode 24 (a transparent electrode) is formed. The metal films of the gate lines 26 and the source lines 27 are electrically conductive.

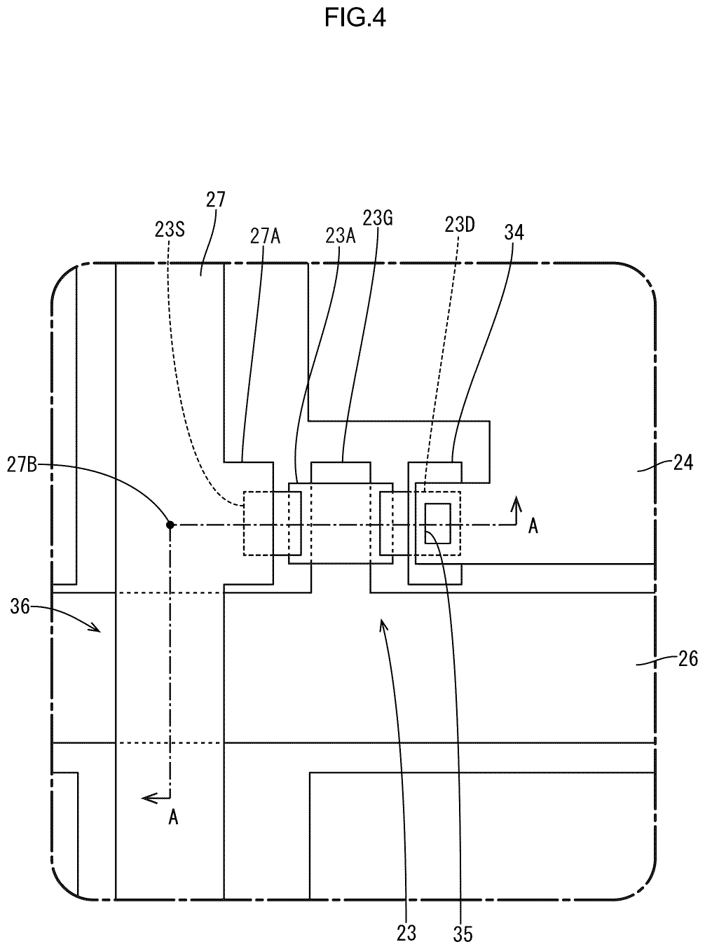

Configurations of the TFTs 23 and the lines 26, 27 will be described with reference to FIG. 4. FIG. 4 is an enlarged plan view of a portion near the TFT 23. As illustrated in FIG. 4, the TFT 23 includes a semiconductor film 23A, a gate electrode 23G, a source electrode 23S, and a drain electrode 23D.

The gate line 26 extending along the X-axis direction is connected to the gate electrode 23G that projects in the Y-axis direction. The gate electrode 23G is disposed to at least overlap the semiconductor film 23A.

A portion of the source line 27 extending along the Y-axis direction is configured as a source projection portion 27A that projects in the X-axis direction. The source projection portion 27A is disposed not to overlap the gate line 26. With such a configuration, a capacitance component is less likely to be created between the source projection portion 27A and the gate line 26.

The source electrode 23S at least partially overlaps the source projection portion 27A. The source electrode 23S overlaps a projecting end portion of the source projection portion 27A. The source projection portion 27A and the source electrode 23S are electrically connected at the overlapping portion with respect to the Z-axis direction and have a same potential. The source electrode 23S is disposed not to overlap the gate line 26 and a capacitance component is less likely to be created between the source electrode 23S and the gate line 26.

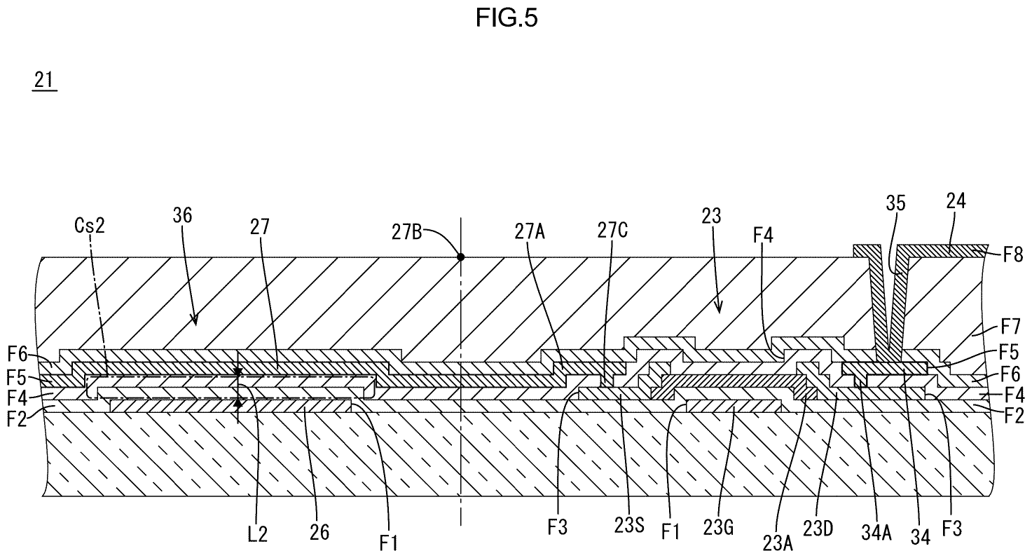

The pixel electrode 24 is connected to the drain electrode 23D via a contact electrode 34 (one example of a relay electrode, see FIG. 5).

The TFT 23 includes the semiconductor film 23A made of semiconductor material. The semiconductor film 23A includes a first end portion that is connected to the source electrode 23S and a second end portion that is connected to the drain electrode 23D. The semiconductor film 23A is disposed to overlap the gate electrode 23G, which is disposed on the back surface side, via the gate insulating film F2.

### 2.1 Various Kinds of Films

Next, films disposed on top of each other on the glass substrate of the array substrate 21 and configured as portions of the lines 26, 27 and the TFTs 23 will be described with reference to FIG. 5. FIG. 5 illustrates a cross-sectional view taken along line A-A in FIG. 4. Line A-A in FIG. 4 extends to laterally cross the TFT 23 along the X-axis direction and is curved at a point 27B on the source line 27 and extends to vertically cross the crossing portion of the source line 27 and the gate line 26 along the Y-axis direction.

On the glass substrate of the array substrate 21, a first metal film F1, the gate insulating film F2 (one example of a first insulating film), the semiconductor film 23A, a second metal film F3, a second insulating film F4, a third metal film F5, a protection film F6, a planarization film F7, and a transparent electrode film F8 are disposed on top of each other in this sequence from a lower layer side (from the glass substrate side).

The first metal film F1, the second metal film F3, and the third metal film F5 are made of metal such as copper and aluminum and have electrically conductive properties. Portions of the first metal film F1 are configured as the gate lines 26 and the gate electrodes 23G of the TFTs 23.

Portions of the second metal film F3 are configured as the source electrodes 23S and the drain electrodes 23D of the TFTs 23. Portions of the third metal film F5 are configured as the source lines 27 and the contact electrodes 34.

The source projection portion 27A, which is a portion of the source line 27, projects in the X-axis direction and a projection end portion of the source projection portion 27A with respect to the X-axis direction overlaps the source electrode 23S. The portion of the source line 27 overlapping the source electrode 23S includes a contact portion 27C that projects in the Z-axis direction and is contacted with the source electrode 23S.

The source line 27 is electrically connected to the source electrode 23S via the contact portion 27C. The contact electrode 34 includes a contact portion 34A at an end portion thereof and is connected to the drain electrode 23D via the contact portion 34A.

The semiconductor film 23A is a thin film made of semiconductor material such as oxide semiconductor and amorphous silicon. The semiconductor film 23A is configured as a channel section of the TFT 23. The gate insulating film F2, the second insulating film F4, and the protection film F6 are made of an inorganic material such as silicon nitride (SiN_{X}) and silicon oxide (SiO₂). The gate insulating film F2 is disposed between the first metal film F1 and the semiconductor film 23A and insulates the first metal film F1 from the semiconductor film 23A. More specifically, with the gate insulating film F2 being disposed between the gate electrode 23G and the semiconductor film 23A of the TFT 23, an electric field is created and a current flowing through the channel section is controlled. The gate insulating film F2 extends to be disposed in an overlapping portion 36 where the gate line 26 and the source line 27 overlap with crossing. The gate insulating film F2 is disposed between the gate lines 26 and the source lines 27 in the overlapping portion 36 to prevent short circuit.

The second insulating film F4 is disposed between the second metal film F3 and the third metal film F5 to prevent short circuit between the second metal film F3 and the third metal film F5. Specifically, short circuits are less likely to be caused in unintended portions except for the contact portions 27C in overlapping portions of the source electrodes 23S and the source lines 27 and the contact portions 34A in overlapping portions of the drain electrodes 23D and the contact electrodes 34. The second insulating film F4 extends to be disposed in the overlapping portion 36 where the gate line 26 and the source line 27 overlap. The second insulating film F4 is disposed between the gate lines 26 and the source lines 27 to prevent short circuit.

The protection film F6 is disposed in a solid manner in a substantially entire area of the array substrate 21 to protect the various kinds of films disposed on the back surface side with respect to the protection film F6. The protection film F6 and the planarization film F7 include a contact hole 35 in portions overlapping the contact electrode 34. The contact hole 35 extends through the protection film F6 and the planarization film F7 in the thickness direction (the Z-axis direction).

The planarization film F7 is made of an organic material such as PMMA (acrylic resin) and is much thicker than other films on the glass substrate. The planarization film F7 planarizes the inner surface (a surface opposite the liquid crystal layer 29) of the array substrate 21.

The transparent electrode film F8 is disposed continuously on an inner peripheral surface and a bottom surface of the contact hole 35 and a surface of the planarization film F7. A portion of the transparent electrode film F8 that is disposed on the inner surface side of the array substrate 21 is configured as the pixel electrode 24. The transparent electrode film F8 is contacted with the contact electrode 34 at the bottom of the contact hole 35 and the pixel electrode 24 is electrically connected to the contact electrode 34 and the drain electrode 23D that is connected to the contact electrode 34.

With the TFT 23 being driven based on a scan signal supplied through the gate line 26, a shade signal (an image signal) that is supplied through the source line 27 is supplied to the pixel electrode 24 via the source electrode 23S, the semiconductor film 23A, the drain electrode 23D, and the contact electrode 34. The pixel electrode 24 is charged at the potential related to the shade signal.

A predefined electric field is applied to the liquid crystal layer 29 based on a potential difference created between the opposed electrode 22 and the pixel electrodes 24. Accordingly, the pixels PX of the liquid crystal panel 11 can perform predefined displaying with shades.

### 2.2 Parasitic Capacitance and Signal Delay

The shade signal input to the TFT 23 through the source line 27 is delayed due to the time constant τs of the source line 27. The time constant τs is represented by the formula of τs=RsCs. Rs represents a resistance value Ω of the source line 27 and Cs represents a parasitic capacitance F of the source line 27.

As illustrated in FIG. 5, the gate line 26 and the source line 27 overlap in the overlapping portion 36 via an insulating member (the gate insulating film F2 and the second insulating film F4). A parasitic capacitance Cs2 is a capacitance component that is created due to a physical structure of the lines 26, 27. As the parasitic capacitance Cs2 increases, the time constant is of the source line 27 increases and the delay of the shade signal input to the TFTs 23 through the source lines 27 also increases.

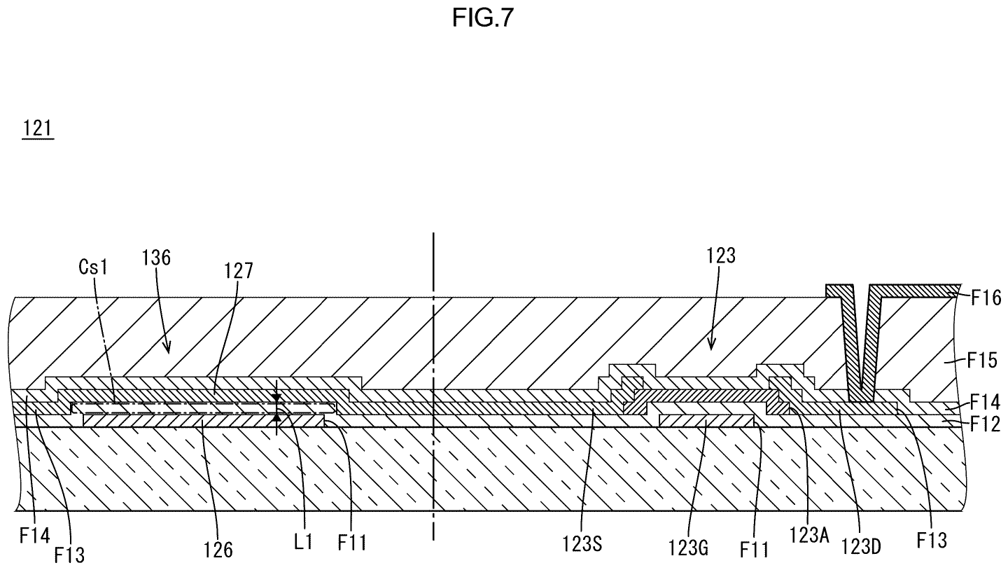

An array substrate 121 of a known configuration will be described with reference to FIG. 7. FIG. 7 is a cross-sectional view of a portion of the array substrate 121 corresponding to the cross-sectional view taken along line A-A in FIG. 4 (a line extending to laterally cross the TFT 23 and extending vertically to cross the overlapping portion 36 of the gate line 26 and the source line 27). The array substrate 121 includes a glass substrate and a first metal film F11, a gate insulating film F12 (a first insulating film), a semiconductor film 123A, a second metal film F13, a protection film F14, a planarization film F15, and a transparent conductive film F16 on the glass substrate.

The first metal film F11 and the second metal film F13 are made of metal such as copper and aluminum and have electrically conductive properties. Portions of the first metal film F11 are configured as gate lines 126 and gate electrodes 123G similar to the first metal film F1 of the array substrate 21. Portions of the second metal film F13 are configured as source electrodes 123S and source lines 127, which are continuously formed, and drain electrodes 123D. The source line 127 corresponds to a portion extending in the Y-axis direction and the source electrode 123S corresponds to a portion projecting from the source line 127 in the X-axis direction and connected to the semiconductor film 123A.

The source electrodes 123S and the source lines 127 of the array substrate 121 are portions of the second metal film F13. This embodiment differs from the array substrate 121 in this configuration. In this embodiment, the metal film (the first metal film F1) of the source electrodes 23S differs from the metal film (the third metal film F5) of the source lines 27 and an insulating member (the second insulating film F4) is between the source electrodes 23S and the source lines 27.

The array substrate 21 includes the contact electrode 34 that is disposed between the drain electrode 23D and the transparent electrode film F8 and connected to the drain electrode 23D and the transparent electrode film F8; however, the array substrate 121 does not include such a configuration. The drain electrode 123D of the array substrate 121 is directly connected to a contact portion that is a portion of the transparent conductive film F16.

The semiconductor film 123A, the protection film F14, the planarization film F15, and the transparent conductive film F16 have similar configurations of those of the semiconductor film 23A, the protection film F6, the planarization film F7, and the transparent electrode film F8 of the array substrate 21, respectively.

The gate insulation film F12 is disposed between the semiconductor film 123A and the gate electrodes 123G and insulates the semiconductor film 123A from the gate electrodes 123G. The gate insulation film F12 is disposed between the gate line 126 and the source line 127 in an overlapping portion 136 where the gate lien 126 and the source line 127 overlap and insulates the gate line 126 from the source line 127.

In the array substrate 121, an insulating member disposed between the gate line 126 and the source line 127 is only the gate insulating film F12. In the array substrate 121, a distance L1 between the gate line 126 and the source line 127 depends on the thickness of the gate insulating film F12.

The thickness of the gate insulating film F12 may be increased to reduce a parasitic capacitance Cs1 of the overlapping portion 136. However, changing of the thickness of the gate insulating film F12 may affect the characteristics of the TFT 123.

### 3. Description of Advantageous Effects

In the array substrate 21 of this embodiment, a distance L2 between the gate line 26 and the source line 27 may be increased to reduce the parasitic capacitance Cs2 of the overlapping portion 36. The array substrate 21 of this embodiment includes the gate line 26, the source line 27 crossing the gate line 26, the TFT 23 disposed on a crossing portion of the gate line 26 and the source line 27, the semiconductor film 23A included in the TFT 23, the gate insulating film F2 disposed in a layer between the gate line 26 and the semiconductor film 23A, and the second insulating film F4 disposed in a layer between the semiconductor film 23A and the source line 27. The source line 27 overlaps the gate line 26 via the gate insulating film F2 and the second insulating film F4.

With such a configuration, as illustrated in FIG. 5, the gate insulating film F2 and the second insulating film F4, which are insulating members, are disposed between the gate line 26 and the source line 27. Even with the thickness of the gate insulating film F2 being same as that of the gate insulating film F12 (see FIG. 7), the distance L2 between the gate line 26 and the source line 27 is greater than the distance L1 (see FIG. 7) by the thickness of the second insulating film F4. The parasitic capacitance Cs2 of the overlapping portion 36 is smaller than the parasitic capacitance Cs1 created with the distance L1. As the parasitic capacitance reduces, the time constant τs is reduced and the delay of signals input to the TFT 23 through the source line 27 is less likely to be caused.

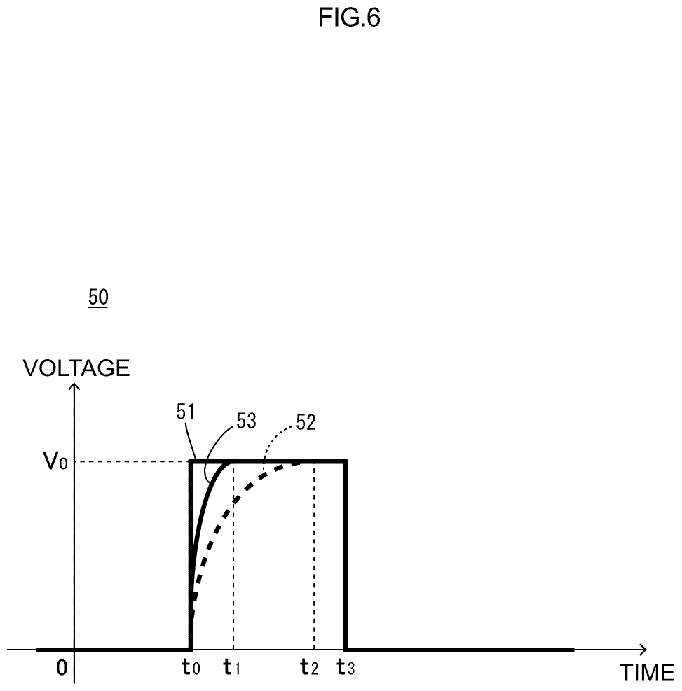

The decrease of signal delay will be described with reference to a graph 50 illustrated in FIG. 6. The graph 50 schematically illustrates waveforms of signals input to the source electrodes 23S, 123S when a shade signal of a square wave (voltage value V0) is input to the source lines 27, 127. In the graph 50, a lateral axis represents time and a vertical axis represents a voltage. A voltage waveform 51 in the graph 50 represents a voltage waveform of a shade signal input to the source line 27. Voltage waveforms 52, 53 represent waveforms of source voltages input to the source electrodes 23S, 123S through the source lines 27, 127, respectively.

According to the voltage waveform 51, the voltage application starts at time t0 and the voltage increases from 0 to V0 at the time t0. The voltage V0 is maintained from the time t0 to time t3 and the voltage drops from V0 to 0. For easy explanation, the voltage of the shade signal increases and drops promptly.

The voltage waveform 52 represents a voltage waveform of the source electrode 123S when the shade signal of the voltage waveform 51 is input to the source line 127 of the array substrate 121 illustrated in FIG. 7. The time constant 11 that is calculated with electrostatic capacity C of the source line 127 being used as the parasitic capacitance Cs1 is applied to the voltage waveform 52.

As illustrated in FIG. 6, according to the voltage waveform 52, the voltage increases from the time t0 as time passes and reaches the voltage V0 at time t2. With the array substrate 121, time obtained by t2-t0 is required until the voltage reaches the voltage V0 after the application of the shade signal (the voltage waveform 51).

With the delay time being defined as the time necessary for the voltage to reach the voltage V0 (time t2) from the shade signal application start time (time t0), the delay time of the array substrate 121 is t2-t0.

The voltage waveform 53 represents a waveform of the voltage of the source electrode 23S when the shade signal of the voltage waveform 51 is input to the source line 27 of the array substrate 21 illustrated in FIG. 5. The time constant τ2 that is calculated with electrostatic capacity C of the source line 27 being used as the parasitic capacitance Cs2 is applied to the voltage waveform 53. As previously described, the distance L2 between the gate line 26 and the source line 27 being greater than the distance L1 (L1<L2), the parasitic capacitance Cs2 is smaller than the parasitic capacitance Cs1 (Cs1>Cs2) and the time constant τ2 is smaller than the time constant τ1 (τ1>τ2).

As illustrated in FIG. 6, the voltage of the voltage waveform 53 increases as the time passes from the time t0 and reaches the voltage V0 at the time t1. The delay time of the array substrate 21 of this embodiment is t1-t0. With the time constant being τ1>τ2, the delay time t1-t0 of the array substrate 21 is shorter than the delay time t2-t0 of the array substrate 121. According to the array substrate 21 of this embodiment, the voltage reaches the voltage V0 with the delay time that is shorter than that of the array substrate 121 and the signal delay of the source line 27 is decreased compared to that of the array substrate 121.

With the delay time being shortened, time necessary for the pixels to display with predefined shades after the input of the shade signals is shortened. Accordingly, high frequency application can be achieved by increasing the refresh rate of the liquid crystal panel 11 and the resolution of the liquid crystal panel 11 can be increased by increasing the number of pixels within the display area AA.

In the array substrate 21 of this embodiment, the TFT 23 includes the source electrode 23S that is connected to the semiconductor film 23A. With the source line 27 being connected to the source electrode 23S, the source line 27 is connected to the semiconductor film 23A via the source electrode 23S and the source electrode 23S is disposed between the gate insulating film F2 and the second insulating film F4.

As illustrated in FIG. 5, the source line 27 is connected to the semiconductor film 23A via the source electrode 23S and therefore, the source line 27 is not directly contacted with the semiconductor film 23A. Without the direct contact, the material and the forming process (such as chemical resistance, annealing temperature) of the source line 27 can be determined without considering the material characteristics of the semiconductor film 23A.

For example, as the material of the source lines 27, material that can be appropriately connected to the source electrode 23S but has low connection ability with respect to the semiconductor film 23A can be used. Furthermore, in the process of forming the source lines 27, chemical liquid that severely degrades the semiconductor film 23A can be used. Accordingly, the material and the forming process of the source lines 27 can be freely determined with respect to the semiconductor film 23A.

With the source electrodes 23S and the source lines 27 being in different layers via the second insulating film F4, the material and the forming process of the source electrodes 23S and the source lines 27 may not be necessarily same. Accordingly, the material and the forming process of the source electrodes 23S and the source lines 27 can be freely determined.

With the source line 27 being connected to the semiconductor film 23A via the source electrode 23S, the arrangement of the source lines 27 with respect to the semiconductor film 23A can be freely determined. For example, even with the semiconductor film 23A being disposed not to overlap the source line 27, the semiconductor film 23A can be electrically connected to the source line 27 via the source electrode 23S.

In the array substrate 21 of this embodiment, the source electrode 23S does not overlap the gate line 26. With the source electrode 23S not overlapping the gate line 26, the capacity component between the source electrode 23S and the gate line 26 becomes smaller compared to the configuration in which the source electrode 23S overlaps the gate line 26. In the transmission of the shade signal to the semiconductor film 23A via the source electrode 23S from the source line 27, the total of the electrostatic capacitance created between the source line 27 and the source electrode 23S, which are connected and have a same potential, and the gate line 26 is decreased and the time constant τ becomes smaller and the signal delay is decreased.

In the array substrate 21 of this embodiment, the TFT 23 includes the drain electrode 23D that is connected to the semiconductor film 23A and the drain electrode 23D is disposed between the gate insulating film F2 and the second insulating film F4.

Accordingly, similar to the relation of the source line 27 and the semiconductor film 23A, the material and the forming process of the drain electrodes 23D can be freely determined.

The liquid crystal display device 10 of this embodiment includes the array substrate 21 and the opposed substrate 20 that is disposed opposite the array substrate 21. According to the liquid crystal display device 10, with the parasitic capacitance Cs2 of the source line 27 is reduced, delay is less likely to be caused in the signals (shade signals) sent through the source line 27. This improves display quality.

### Other Embodiments

(1) In the above embodiment, the TFT 23 (the switching component) includes the semiconductor film 23A, the source electrode 23S, and the drain electrode 23D. The switching component may not include one or both of the source electrode and the drain electrode. With such a configuration, a portion of the semiconductor film is processed to be electrically conductive and the source line or the contact electrode is contacted with the processed electrically conductive portion. Accordingly, the source line or the contact electrode is electrically connected to the switching component.
(2) In the above embodiment, the source electrode 23S does not overlap the gate line 26. A portion of the source electrode 23S or the entire source electrode 23S may overlap the gate line 26.
(3) In the above embodiment, the TFTs 23 are bottom-gate type transistors in which the gate electrode 23G is on the back surface side with respect to the semiconductor film 23A with having the gate insulating film F2 therebetween. The TFTs 23 may not be the bottom-gate type transistors but may be top-gate type transistors or double gate type transistors. The top-gate type transistor includes the gate electrode on the front surface side with respect to the semiconductor film. The double gate type transistor includes gate electrodes on the front surface side and the back surface side with respect to the semiconductor film.
(4) In the above embodiment, the TFTs are described as an example of the switching components. The switching components may not be the TFTs but may be other types of transistors (such as MOSFET, IGBT).
(5) The liquid crystal panel may be driven with the source shared driving (SSD) method. In the SSD method, the display area AA is divided into sections and source signals are transmitted from one TFT to one of the divided sections. In the array substrate of this embodiment, the delay time is shortened and quick switching can be performed. With using the TFTs that can perform quick switching in the SSD type liquid crystal panel, the number of divided sections of the display area can be increased.
(6) In the above embodiment, the opposed electrode 22 is disposed on the opposed substrate 20 and orientations of the liquid crystal molecules included in the liquid crystal layer 29 are controlled with using vertical field effect created between the pixel electrode 24 and the opposed electrode 22 (a vertical field effect liquid crystal mode). Lateral field effect may be created in the liquid crystal layer 29 and orientations of the liquid crystal molecules included in the liquid crystal layer 29 may be controlled with using lateral field effect (a lateral field effect liquid crystal mode). With using the lateral field effect liquid crystal mode, in addition to the configuration including the opposed electrode 22 on the opposed substrate 20, the array substrate 21 may include a common electrode that overlaps the pixel electrodes 24 via an insulating film to create lateral field effect between the pixel electrode 24 and the common electrode.

1. An array substrate comprising:
a gate line;
a source line crossing the gate line;
a switching component disposed on a crossing portion of the gate line and the source line;
a semiconductor film included in the switching component;
a first insulating film disposed between a layer including the gate line and a layer including the semiconductor film; and
a second insulating film disposed between a layer including the semiconductor film and a layer including the source line, wherein
the source line overlaps the gate line via the first insulating film and the second insulating film.

2. The array substrate according to claim 1, wherein
the switching component includes a source electrode that is connected to the semiconductor film,
the source line is connected to the source electrode and is connected to the semiconductor film via the source electrode, and
the source electrode is disposed between the first insulating film and the second insulating film.

3. The array substrate according to claim 2, wherein the source electrode does not overlap the gate line.

4. The array substrate according to claim 2, further comprising a relay electrode, wherein
the switching component includes a drain electrode that is connected to the semiconductor film,
the relay electrode is connected to the drain electrode and is connected to the semiconductor film via the drain electrode, and
the drain electrode is disposed between the first insulating film and the second insulating film.

5. A display device comprising:
the array substrate according to claim 1; and
an opposed substrate opposed to the array substrate.
